(19) United States
(12) Patent Application Publication
(10) Pub. No.: US 2023/0281894 A1
(43) Pub. Date: Sep. 7, 2023

(54) ANALYSIS SYSTEM AND METHOD FOR SIGNAL EYE DIAGRAMS

(71) Applicant: CHANGXIN MEMORY TECHOLOGIES, INC., Hefei City (CN)

(72) Inventors: Kang ZHAO, Hefei City (CN); Chuanjiang CHEN, Hefei City (CN); Li BAI, Hefei City (CN)

(21) Appl. No.: 17/805,997

(22) Filed: Jun. 8, 2022

Related U.S. Application Data
(63) Continuation of application No. PCT/CN2022/079993, filed on Mar. 9, 2022.

(30) Foreign Application Priority Data
Mar. 2, 2022 (CN) 202210200273.5

(51) Int. Cl. G06T 11/20; G06T 11/00; G06T 3/40; G06T 7/68

(52) U.S. Cl. CPC G06T 11/206; G06T 11/001; G06T 3/40; G06T 7/68

(57) ABSTRACT

Embodiments of the present disclosure relate to the field of semiconductor circuit design and provide an analysis system for signal eye diagrams and method. The analysis system includes: a display structure, configured to receive a plurality of pieces of first display information of a plurality of groups of signal eye diagrams, receive second display information of a standard effective region generated based on an industry standard, display all the signal eye diagrams based on the first display information, and display an outer edge of the standard effective region based on the second display information, where each signal eye diagram corresponds to one piece of first display information, different signal eye diagrams are located in different layers, and different signal eye diagrams are displayed in different ways.

### CROSS-REFERENCE TO RELATED APPLICATIONS

This is a continuation of International Application No. PCT/CN2022/079993, filed on Mar. 9, 2022, which claims the benefit and priority of Chinese Patent Application No. 202210200273.5, filed on Mar. 2, 2022 and entitled “ANALYSIS SYSTEM AND METHOD FOR SIGNAL EYE DIAGRAMS”. The entire contents of International Application No. PCT/CN2022/079993 and Chinese Patent Application No. 202210200273.5 are incorporated herein by reference.

### TECHNICAL FIELD

Embodiments of the present disclosure relate to the field of semiconductor circuit design, and in particular to, an analysis system and method for signal eye diagrams.

### BACKGROUND

Currently, a conventional high-speed parallel storage circuit technology such as a double data rate (DDR) series memory is widely used. Compared with a DDR2/3, the new-generation DDR4 and future DDRS have greatly improved the memory access rate, which imposes more stringent requirements on the memory access signal channel. A data eye diagram generator can be used to test performance of a signal channel of a high-speed receiver related to a storage interface. The data eye diagram generator can be configured to generate a data eye diagram of a receiver/buffer. Because the generated data eye diagram is relatively similar to a real data signal passing through the channel, a behavior of the receiver and a channel equalization solution may be described by using the tool.

### SUMMARY

According to some embodiments of the present disclosure, in one aspect of the embodiments of the present disclosure, an analysis system for signal eye diagrams is provided, including a display structure, configured to receive a plurality of pieces of first display information of a plurality of groups of signal eye diagrams, receive second display information of a standard effective region generated based on an industry standard, display all the signal eye diagrams based on the first display information, and display an outer edge of the standard effective region based on the second display information, where each signal eye diagram corresponds to one piece of first display information, different signal eye diagrams are located in different layers, and different signal eye diagrams are displayed in different ways.

According to some embodiments of the present disclosure, in another aspect of the embodiments of the present disclosure, a method for analysing signal eye diagrams is provided, including: receiving a plurality of pieces of first display information of a plurality of groups of signal eye diagrams, and receiving second display information of a standard effective region generated based on an industry standard; and displaying all the signal eye diagrams based on the first display information, and displaying an outer edge of the standard effective region based on the second display information, where each signal eye diagram corresponds to one piece of first display information, different signal eye diagrams are located in different layers, and different signal eye diagrams are displayed in different ways.

### BRIEF DESCRIPTION OF THE DRAWINGS

One or more embodiments are described illustratively by use of corresponding drawings. The illustrative description does not constitute any limitation on the embodiments. Unless otherwise expressly specified, the drawings do not constitute a scale limitation. To describe the technical solutions in the embodiments of the present disclosure or in the conventional technology more clearly, the following simply describes the drawings to be used in the embodiments of the present disclosure. Evidently, the drawings outlined below are merely some embodiments of the present disclosure. A person of ordinary skill in the art may derive other drawings from the outlined drawings without making any creative effort.

FIG. 1 is a schematic structural diagram of functional modules of an analysis system for signal eye diagrams according to an embodiment of the present disclosure;

FIG. 2 is display schematic diagram generated by an analysis system for signal eye diagrams according to an embodiment of the present disclosure;

FIG. 3 is a display schematic diagram of a first signal eye diagram, a second signal eye diagram, and an overlapping region in FIG. 2;

FIG. 4 is another display schematic diagram generated by an analysis system for signal eye diagrams according to an embodiment of the present disclosure;

FIG. 5 is a display schematic diagram of a third signal eye diagram, a fourth signal eye diagram, and an overlapping region in FIG. 4; and

FIG. 6 is a flowchart of a method for analysing signal eye diagrams according to another embodiment of the present disclosure.

### DETAILED DESCRIPTION

Embodiments of the present disclosure provide an analysis system and method for signal eye diagrams In the analysis system for signal eye diagrams, a display structure may display a plurality of different signal eye diagrams simultaneously, and in the display structure, different signal eye diagrams do not interfere with each other, so that a user can intuitively observe a plurality of signal eye diagrams. In addition, the display structure further displays an outer edge of a standard effective region. By respectively comparing position relationships between the plurality of signal eye diagrams and the outer edge of the standard effective region, the user can intuitively determine the quality of the plurality of signal eye diagrams.

The embodiments of the present disclosure are described in detail below with reference to the accompanying drawings. However, a person skilled in the art may understand that in each embodiment of the present disclosure, many technical details are proposed to help readers better understand the embodiments of the present disclosure. However, the technical solutions claimed in the embodiments of the present disclosure can still be implemented based on variations and modifications of the following embodiments even without the technical details.

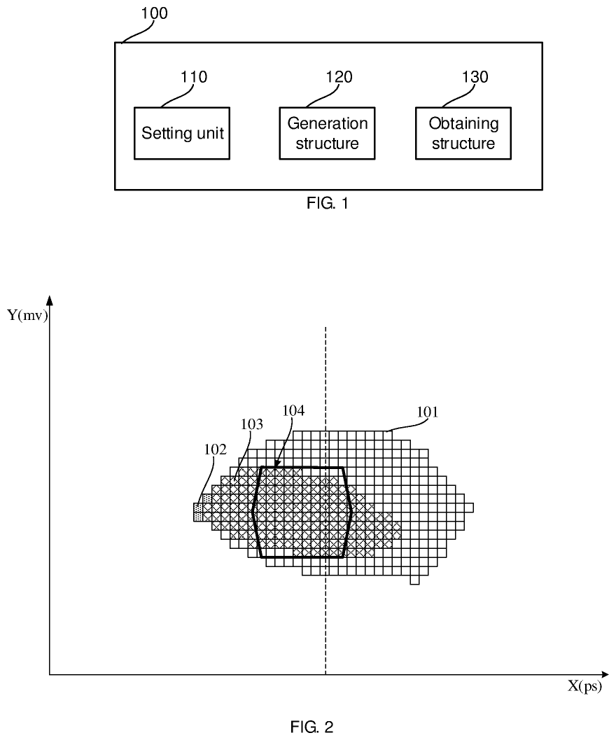

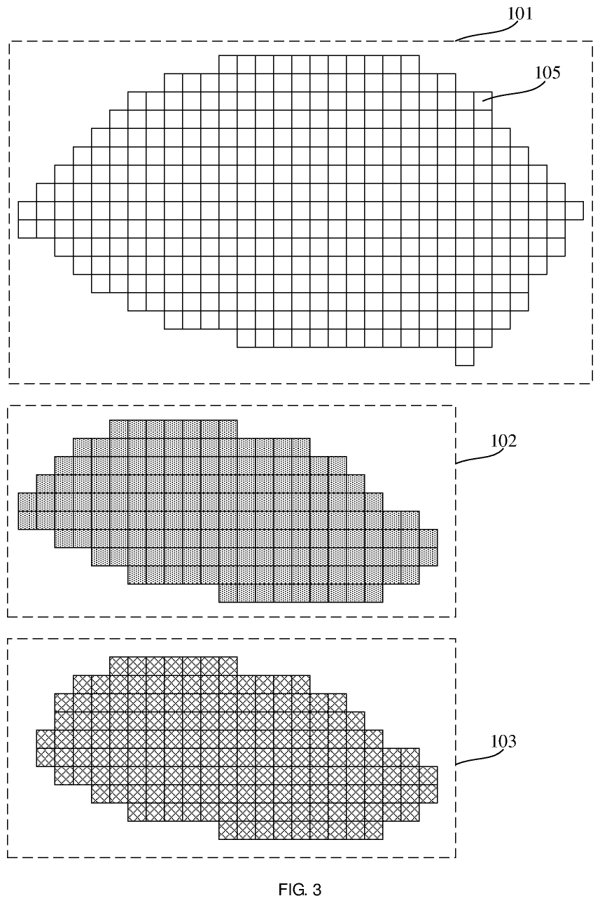

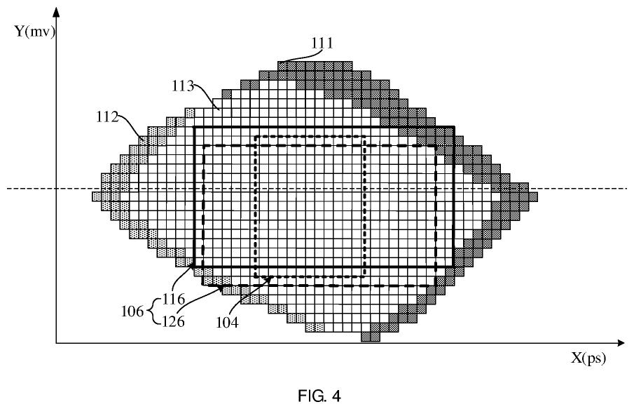

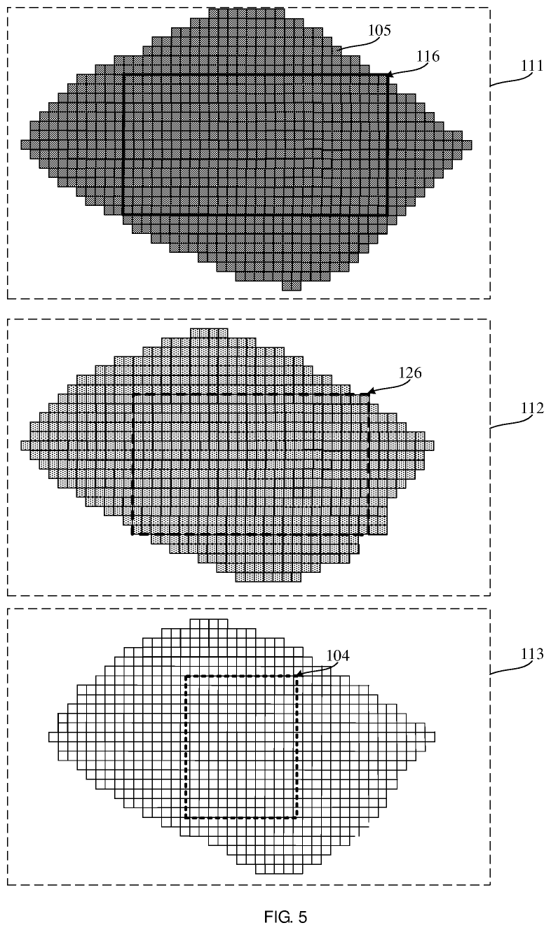

An embodiment of the present disclosure provides an analysis system for signal eye diagrams. The analysis system for signal eye diagrams provided by the embodiment of the present disclosure is described in detail below with reference to the drawings. FIG. 1 is a schematic structural diagram of functional modules of an analysis system for signal eye diagrams according to an embodiment of the present disclosure; FIG. 2 is a display schematic diagram generated by an analysis system for signal eye diagrams according to an embodiment of the present disclosure; FIG. 3 is a display schematic diagram of a first signal eye diagram, a second signal eye diagram, and an overlapping region in FIG. 2; FIG. 4 is another display schematic diagram generated by an analysis system for signal eye diagrams according to an embodiment of the present disclosure; and FIG. 5 is a display schematic diagram of a third signal eye diagram, a fourth signal eye diagram, and an overlapping region in FIG. 4.

Referring to FIG. 1, the analysis system for signal eye diagrams includes: a display structure 100, configured to receive a plurality of pieces of first display information of a plurality of groups of signal eye diagrams, receive second display information of a standard effective region 104 generated based on an industry standard, display all the signal eye diagrams based on the first display information, and display an outer edge of the standard effective region 104 based on the second display information, where each signal eye diagram corresponds to one piece of first display information, different signal eye diagrams are located in different layers, and different signal eye diagrams are displayed in different ways.

In some embodiments, the industry standard includes a joint electron device engineering council (JEDEC) standard. It should be noted that a JEDEC is a leading standard mechanism of a microelectronics industry. The JEDEC standard is a standard developed by the JEDEC for the emerging semiconductor industry, which is accepted and adopted by the industry. In this embodiment of the present disclosure, if the entire region of a signal eye diagram covers the outer edge of the standard effective region 104, it may be understood that the standard effective region 104 is located in the signal eye diagram, and it may be determined that the signal eye diagram has a relatively low level of bit error rate, and the quality of the signal eye diagrams meets a requirement. Therefore, it may be determined that a channel design corresponding to the signal eye diagram meets a standard requirement.

Referring to FIG. 2 and FIG. 3, the display structure displays a first signal eye diagram 101 and a second signal eye diagram 102. A display mode of the first signal eye diagram 101 is different from that of the second signal eye diagram 102. A user can intuitively observe an entirely displayed shape of the first signal eye diagram 101 and an entirely displayed shape of the second signal eye diagram 102. In addition, a display mode of an overlapping region 103 between the first signal eye diagram 101 and the second signal eye diagram 102 is different from the display mode of the first signal eye diagram 101 and the display mode of the second signal eye diagram 102. It should be noted that FIG. 1 and FIG. 2 are merely display modes of the first signal eye diagram 101, the second signal eye diagram 102, and the overlapping region 103. In an actual application, the display modes of the first signal eye diagram 101, the second signal eye diagram 102, and the overlapping region 103 are not limited provided that the user can intuitively distinguish the first signal eye diagram 101, the second signal eye diagram 102, and the overlapping region 103.

It should be noted that in FIG. 2, a horizontal axis X represents a scanning period of the signal eye diagram, and a longitudinal axis Y represents a signal swing of the signal eye diagram.

In some embodiments, referring to FIG. 2 and FIG. 3, the signal eye diagram may be formed by a plurality of rectangles 105 having a same size and closely connected in a grid-like structure. tstep may be used for representing a step size of the scanning period, that is, a scale represented by a length of a single rectangle 105, and vstep may be used for representing a step size of the signal swing, that is, a scale represented by a width of a single rectangle 105.

In this embodiment of the present disclosure, different signal eye diagrams are displayed in different ways, and the display of different signal eye diagrams in the display structure 100 does not interference with each other, so that the user can intuitively observe a plurality of signal eye diagrams. In addition, the display structure 100 further displays an outer edge of the standard effective region 104. By respectively com paring position relationships between the signal eye diagrams and the outer edge of the standard effective region 104, the user can intuitively determine whether the quality of the plurality of signal eye diagrams meets a requirement, thereby improving the analysis efficiency of the signal eye diagram. In addition, the entire region of the signal eye diagram is displayed in the display structure 100, and only the outer edge of the standard effective region 104 is displayed in the display structure 100, which is beneficial to increasing a difference between display forms of the signal eye diagram and the standard effective region 104 in the display structure 100, thereby avoiding confusion between the signal eye diagram and the standard effective region 104 to the user. For example, when there are partial overlapping regions between the signal eye diagrams and the standard effective region 104, the display structure 100 displays only the outer edge of the standard effective region 104, so that the user can obviously learn a region occupied by the standard effective region 104 and does not confuse the standard effective region with the signal eye diagram, thereby preventing the standard effective region 104 from covering a void defect of an intermediate region in the signal eye diagram.

In some embodiments, in the display structure, different signal eye diagrams may be displayed in different colors, and colors displayed in overlapping regions of a plurality of signal eye diagrams are different from a color displayed in a non-overlapping region of any one of the signal eye diagrams. For example, the first signal eye diagram 101 may be displayed as purple, the second signal eye diagram 102 may be displayed as pink, and the overlapping region 103 between the first signal eye diagram 101 and the second signal eye diagram 102 may be displayed as blue.

In some embodiments, continue to refer to FIG. 1 to FIG. 3, the signal eye diagram may be formed by a plurality of rectangles 105 having a same size and closely connected in a grid-like structure. The display structure 100 may include a setting unit 110, configured to set a scale represented by each of a length and a width of the rectangle 105 and set a size of the rectangle 105 and a color displayed in the rectangle 105. It may be understood that the size of the rectangle 105 means values of a length and a width of a single rectangle 105 in the display structure. The scale represented by each of the length and the width of the rectangle 105 means a value of a parameter represented by the length of the rectangle 105 along a coordinate axis corresponding to the length and a value of a parameter represented by the width of the rectangle 105 along a coordinate axis corresponding to the width. The color displayed in the rectangle 105 means a color required to be displayed in the signal eye diagram. In another embodiment, the signal eye diagram may be formed by a plurality of circles having a same size and arranged in an array or formed by a point array.

In some embodiments, the display structure 100 may further be configured to set a quantity of displayed signal eye diagrams. Referring to FIG. 2, the display structure 100 may display two signal eye diagrams, that is, the first signal eye diagram 101 and the second signal eye diagram 102. In an actual application, the display structure 100 may display three, four, or five signal eye diagrams. Therefore, it is beneficial for the user to analyze a plurality of signal eye diagrams simultaneously, and it is convenient for the user to quickly determine whether the quality of each signal eye diagram meets the requirement, thereby improving the analysis efficiency of the signal eye diagrams.

In some embodiments, referring to FIG. 1 and FIG. 2, the standard effective region 104 may have a central symmetry structure. The display structure 100 may include a setting unit 110, configured to change an area of the standard effective region 104 without changing a center of symmetry of the standard effective region 104, to generate third display information of a target effective region. The display structure 100 displays the target effective region based on the third display information. Therefore, it is beneficial for the user to continuously adjust a shape of the standard effective region 104 according to characteristics of to-be-analyzed signal eye diagrams after the standard effective region 104 is generated based on the industry standard, to meet analysis requirements of a developer in different scenarios.

It should be noted that the standard effective region 104 is not modified in FIG. 2. In an example, referring to FIG. 2, the standard effective region 104 may be a hexagon. In another example, the standard effective region may alternatively have a central symmetry structure such as a rectangle, a regular hexagon, an octagon, or a circle.

How to change the area of the standard effective region 104 without changing the center of symmetry of the standard effective region 104 is described below by using two embodiments in detail.

In some embodiments, the setting unit 110 may be configured to set a ratio of an area of the target effective region to the area of the standard effective region 104, to generate the third display information of the target effective region, that is, the target effective region may be obtained by magnifying or reducing the standard effective region 104 in an equal proportion.

In some other embodiments, the setting unit 110 may be configured to change at least a side length or a side width of the standard effective region 104, to generate the third display information of the target effective region. For example, if the standard effective region 104 is a rectangle, only a length or a width of the rectangle may be changed, to generate the target effective region; or a length and a width of the rectangle are changed simultaneously, to generate the target effective region.

How to determine the center of symmetry of the standard effective region is described below by using two embodiments in detail.

In some embodiments, the plurality of signal eye diagrams have overlapping regions 103, the standard effective region 104 is a central symmetry structure, and the standard effective region 104 has a center of symmetry. The display structure 100 may be configured to determine a horizontal coordinate of the center of symmetry based on a midpoint between two points of which horizontal coordinates have a largest difference in the overlapping regions 103; and determine a longitudinal coordinate of the center of symmetry based on a midpoint between two points of which longitudinal coordinates have a largest difference in the overlapping regions 103.

In some other embodiments, the plurality of signal eye diagrams have overlapping regions 103, the standard effective region 104 is a central symmetry structure, and the standard effective region 104 has a center of symmetry. The display structure 100 may be configured to: set a horizontal axis X and a longitudinal axis Y that are perpendicular to each other, where the horizontal axis X represents a scanning period of the signal eye diagram, and the longitudinal axis Y represents a signal swing of the signal eye diagram; determine a horizontal coordinate of the center of symmetry based on a midpoint of the scanning period on the horizontal axis X; and determine a longitudinal coordinate of the center of symmetry based on a midpoint on the longitudinal axis Y.

In another embodiment, the horizontal coordinate of the center of symmetry may be determined based on a midpoint of an actual scanning period of the signal eye diagram and the longitudinal coordinate of the center of symmetry may be determined based on a midpoint of an actual signal swing of the signal eye diagram.

In some embodiments, the analysis system for signal eye diagrams may further include a generation structure 120. The generation structure 120 includes a first mode and a second mode. The first mode is used for simulating signal transmission performance of an interface for receiving a data signal, and the second mode is used for simulating signal transmission performance of an interface for receiving a command signal and/or an address signal. The standard effective region 104 generated by the generation structure 120 in the first mode is different from the standard effective region 104 generated in the second mode. Therefore, signal eye diagram analysis may be performed on interfaces with different purposes by using different modes, to simulate and analyze performance of signal channels provided by different interfaces, which is beneficial to improving the analysis accuracy of the signal eye diagram and improving the universality of the analysis system for signal eye diagrams. It should be noted that the foregoing embodiments provide only two modes. In an actual application, the mode that can be provided by the generation structure is not limited, and different modes may be set for purposes of the interfaces.

Referring to FIG. 4 and FIG. 5, the generation structure 120 may further be configured to generate fourth display information of eye diagram effective regions 106 in one to one correspondence with the signal eye diagrams based on the signal eye diagrams. The display structure 100 may be configured to display outer edges of the eye diagram effective regions 106 based on the fourth display information. A type of an area defined by the eye diagram effective region 106 is the same as a type of an area defined by the standard effective region 104.

It may be understood that the type of the figure defined by the eye diagram effective region 106 is the same as the type of the figure defined by the standard effective region 104, that is, if the figure defined by the standard effective region 104 is a rectangle, the figure defined by the eye diagram effective region 106 is a rectangle. The standard effective region 104 and the eye diagram effective region 106 are generated based on a same standard, to facilitate subsequently determining the quality of the signal eye diagrams based on the standard effective region 104 and the eye diagram effective region 106.

Referring to FIG. 4 and FIG. 5, the display structure 100 (referring to FIG. 1) displays a third signal eye diagram 111, a fourth signal eye diagram 112, and the standard effective region 104. The third signal eye diagram 111 has a third eye diagram effective region 116, and the fourth signal eye diagram 112 has a fourth eye diagram effective region 126. It should be noted that FIG. 4 and FIG. 5 are merely display modes of the third eye diagram effective region 116, the fourth eye diagram effective region 126, and the standard effective region 104. In an actual application, the display modes of the third eye diagram effective region 116, the fourth eye diagram effective region 126, and the standard effective region 104 are not limited provided that the user can intuitively distinguish the third eye diagram effective region 116, the fourth eye diagram effective region 126, and the standard effective region 104. For example, an edge of the third eye diagram effective region 116 may be displayed as blue, an edge of the fourth eye diagram effective region 126 may be displayed as red, and an edge of the standard effective region 104 may be displayed as green.

A display mode of the third signal eye diagram 111 is different from that of the fourth signal eye diagram 112. A user can intuitively observe an entirely displayed shape of the third signal eye diagram 111 and an entirely displayed shape of the fourth signal eye diagram 112. In addition, a display mode of an overlapping region 113 between the third signal eye diagram 111 and the fourth signal eye diagram 112 is different from the display mode of the third signal eye diagram 111 and the display mode of the fourth signal eye diagram 112. It should be noted that FIG. 4 and FIG. 5 are merely display modes of the third signal eye diagram 111, the fourth signal eye diagram 112, and the overlapping region 113. In an actual application, the display modes of the third signal eye diagram 111, the fourth signal eye diagram 112, and the overlapping region 113 are not limited provided that the user can intuitively distinguish the third signal eye diagram 111, the fourth signal eye diagram 112, and the overlapping region 113.

It should be noted that in FIG. 4, an X axis represents a scanning period of the signal eye diagram, and a Y axis represents a signal swing of the signal eye diagram.

In some embodiments, referring to FIG. 4 and FIG. 5, the signal eye diagram may be formed by a plurality of rectangles 105 having a same size and closely connected in a grid-like structure. tstep may be used for representing a step size of the scanning period, that is, a scale represented by a length of a single rectangle 105, and vstep may be used for representing a step size of the signal swing, that is, a scale represented by a width of a single rectangle 105.

In some embodiments, continue to refer to FIG. 4 and FIG. 5, the analysis system for signal eye diagrams may further determine, based on the standard effective region 104, whether the signal eye diagram is offset, to evaluate the quality of the signal eye diagrams. How to determine the quality of the signal eye diagrams based on the standard effective region 104 is described below by using four embodiments in detail.

In some embodiments, referring to FIG. 1 to FIG. 5, the display structure 100 may be configured to set a horizontal axis X and a longitudinal axis Y that are perpendicular to each other, where the horizontal axis X represents a scanning period of the signal eye diagram, and the longitudinal axis Y represents a signal swing of the signal eye diagram. The analysis system for signal eye diagrams may further include an obtaining structure 130, configured to select any eye diagram effective region 106 as a target eye diagram effective region and the signal eye diagram corresponding to the target eye diagram effective region as a target signal eye diagram, where in a direction of the horizontal axis X, the target eye diagram effective region has a first left reference value located at a leftmost side and a first right reference value located at a rightmost side, the standard effective region 104 has a second left reference value located at a leftmost side and a second right reference value located at a rightmost side, the first left reference value is subtracted from the second left reference value to generate a left offset, and the second right reference value is subtracted from the first right reference value to generate a right offset. In an example, if the third signal eye diagram 111 is a target signal eye diagram, a third eye diagram effective region 116 corresponding to the third signal eye diagram 111 is a target eye diagram effective region, a first left reference value of the third eye diagram effective region 116 is a value of an edge, which is located at a leftmost side and represented on the horizontal axis X, of the third eye diagram effective region 116, and a first right reference value of the third eye diagram effective region 116 is a value of an edge, which is located at a rightmost side and represented on the horizontal axis X, of the third eye diagram effective region 116, a second left reference value is a value of an edge, which is located at a leftmost side and represented on the horizontal axis X, of the standard effective region 104, and a second right reference value is a value of an edge, which is located at a rightmost side and represented on the horizontal axis X, of the standard effective region 104.

It may be learned by comparing a position relationship between the third eye diagram effective region 116 and the standard effective region 104 in FIG. 4 that the first left reference value is located at the left side of the second left reference value, the left offset is a positive value, and the user may determine that the left edge of the third signal eye diagram 111 meets a requirement compared with the standard effective region 104; and the first right reference value is located at the right side of the second right reference value, the right offset is a positive value, and the user may determine that the right edge of the third signal eye diagram 111 meets the requirement compared with the standard effective region 104. In another embodiment, there may be a case that one of the left offset or the right offset is a positive value, and the other is a negative value or there may be a case that both the left offset and the right offset are negative values, and the user may determine that at least one of the right edge or the left edge of the third signal eye diagram 111 does not meet the requirement compared with the standard effective region 104.

In some other embodiments, referring to FIG. 1 to FIG. 5, the signal eye diagram is displayed as a grid-like structure formed by a plurality of rectangles 105 having a same size and closely connected. The display structure 100 may be configured to set a horizontal axis X and a longitudinal axis Y that are perpendicular to each other, where the horizontal axis X represents a scanning period of the signal eye diagram, and the longitudinal axis Y represents a signal swing of the signal eye diagram. The analysis system for signal eye diagrams may further include an obtaining structure 130, configured to select any eye diagram effective region 106 as a target eye diagram effective region and the signal eye diagram corresponding to the target eye diagram effective region as a target signal eye diagram, where in a direction of the horizontal axis X, the target eye diagram effective region has a first left boundary located at a leftmost side and a first right boundary located at a rightmost side, the standard effective region 104 has a second left boundary located at a leftmost side and a second right boundary located at a rightmost side, a quantity of rectangles 105 included between the first left boundary and the longitudinal axis Y is subtracted from a quantity of rectangles 105 included between the second left boundary and the longitudinal axis Y to generate a left offset value, and a quantity of rectangles 105 included between the second right boundary and the longitudinal axis Y is subtracted from a quantity of rectangles 105 included between the first right boundary and the longitudinal axis Y to generate a right offset value; and generate a left offset based on a product of the left offset value and a scale represented by a length of the rectangles 105 in the direction of the horizontal axis X, and generate a right offset based on a product of the right offset value and a scale represented by the length of the rectangles in the direction of the horizontal axis X. Therefore, the user may intuitively and rapidly obtain the left offset and the right offset of the target signal eye diagram by using the quantity of rectangles 105, which is beneficial to further improving the analysis efficiency and the analysis accuracy of the signal eye diagram.

In another embodiment, the obtaining structure may alternatively be configured to use a difference obtained by subtracting a quantity of rectangles included between the first left boundary and the longitudinal axis from a quantity of rectangles included between the second left boundary and the longitudinal axis as the left offset and use a difference obtained by subtracting a quantity of rectangles included between the second right boundary and the longitudinal axis from a quantity of rectangles included between the first right boundary and the longitudinal axis as the right offset, that is, both the right offset and the left offset represent the quantities of rectangles.

In the two embodiments, the obtaining structure 130 may further be configured to generate a timing margin of the target signal eye diagram based on a sum of the left offset and the right offset after obtaining the left offset and the right offset.

It should be noted that the area of the standard effective region 104 may be changed without changing the center of symmetry of the standard effective region 104, to generate the target effective region, so that the second left boundary is a boundary, located at a leftmost side, of the target effective region, and the second right boundary is a boundary, located at a rightmost side, of the target effective region. The user may determine the quality of the target signal eye diagram based on the target effective region and the target eye diagram effective region. When the area of the standard effective region 104 is changed without changing the center of symmetry of the standard effective region 104, an edge of the generated target effective region may overlap with an edge of the rectangle 105. Therefore, the user intuitively and rapidly obtains a quantity of rectangles 105 between the second left boundary and the first left boundary from the display structure 100 and intuitively and rapidly obtains a quantity of rectangles 105 between the first right boundary and the second right boundary from the display structure 100, which is beneficial to subsequently obtaining the left offset value and the right offset value. In addition, a manner of determining, based on positive or negative of the left offset and the right offset, whether the signal eye diagram is offset is the same as that in the foregoing embodiments. Details are not described herein again.

In some other embodiments, referring to FIG. 1 to FIG. 5, the display structure 100 may be configured to set a horizontal axis and a longitudinal axis that are perpendicular to each other, where the horizontal axis represents a scanning period of the signal eye diagram, and the longitudinal axis represents a signal swing of the signal eye diagram. The analysis system for signal eye diagrams may further include an obtaining structure, configured to select any eye diagram effective region as a target eye diagram effective region and the signal eye diagram corresponding to the target eye diagram effective region as a target signal eye diagram, where in a direction of the longitudinal axis, the target eye diagram effective region has a first upper reference value located at an uppermost end and a first lower reference value located at a lowermost end, the standard effective region has a second upper reference value located at an uppermost end and a second lower reference value located at a lowermost end, the second upper reference value is subtracted from the first upper reference value to generate an upper offset, and the first lower reference value is subtracted from the second lower reference value to generate a lower offset.

In an example, if the third signal eye diagram 111 is a target signal eye diagram, a third eye diagram effective region 116 corresponding to the third signal eye diagram 111 is a target eye diagram effective region, a first upper reference value of the third eye diagram effective region 116 is a value of an edge, located at an uppermost side and represented on the longitudinal axis Y, of the third eye diagram effective region 116, and a first lower reference value of the third eye diagram effective region 116 is a value of an edge, located at a lowermost side and represented on the longitudinal axis Y, of the third eye diagram effective region 116, a second upper reference value is a value of an edge, located at an uppermost side and represented on the longitudinal axis Y, of the standard effective region 104, and a second lower reference value is a value of an edge, located at a lowermost side and represented on the longitudinal axis Y, of the standard effective region 104. It may be learned by comparing a position relationship between the third eye diagram effective region 116 and the standard effective region 104 in FIG. 4 that the first upper reference value is located at the upper side of the second upper reference value, the upper offset is a positive value, and the user may determine that the upper side of the third signal eye diagram 111 does not offset compared with the standard effective region 104; and the first lower reference value is located at the upper side of the second lower reference value, the lower offset is a negative value, and the user may determine that the lower side edge of the third signal eye diagram 111 does not meet a requirement compared with the standard effective region 104. In another embodiment, there may be a case that the upper offset is a negative value, and the lower offset is a positive value, and the user may determine that the upper side edge of the third signal eye diagram 111 does not meet the requirement compared with the standard effective region 104; or there may be a case that both the upper offset and the lower offset are negative values, and the user may determine that both the upper and lower side edges of the third signal eye diagram 111 do not meet the requirement compared with the standard effective region 104; or there be a case that both the upper offset and the lower offset are positive values, and the user may determine that both the upper and lower side edges of the third signal eye diagram 111 meet the requirement compared with the standard effective region 104.

In still some embodiments, referring to FIG. 1 to FIG. 5, the signal eye diagram is displayed as a grid-like structure formed by a plurality of rectangles having a same size and closely connected. The display structure may be configured to set a horizontal axis and a longitudinal axis that are perpendicular to each other, where the horizontal axis represents a scanning period of the signal eye diagram, and the longitudinal axis represents a signal swing of the signal eye diagram. The analysis system for signal eye diagrams may further include an obtaining structure, configured to select any eye diagram effective region as a target eye diagram effective region and the signal eye diagram corresponding to the target eye diagram effective region as a target signal eye diagram, where in a direction of the longitudinal axis, the target eye diagram effective region has a first upper boundary located at an uppermost end and a first lower boundary located at a lowermost end, the standard effective region has a second upper boundary located at an uppermost end and a second lower boundary located at a lowermost end, a quantity of rectangles included between the second upper boundary and the horizontal axis X is subtracted from a quantity of rectangles included between the first upper boundary and the horizontal axis X to generate an upper offset value, and a quantity of rectangles included between the first lower boundary and the horizontal axis X is subtracted from a quantity of rectangles included between the second lower boundary and the horizontal axis X to generate a lower offset value; generate an upper offset based on a product of the upper offset value and a scale represented by a length of the rectangles in the direction of the longitudinal axis Y, and generate a lower offset based on a product of the lower offset value and a scale represented by the length of the rectangles in the direction of the longitudinal axis Y; and generate a swing margin of the target signal eye diagram based on a sum of the upper offset and the lower offset. Therefore, the user may intuitively and rapidly obtain the upper offset and the lower offset of the target signal eye diagram by using the quantity of rectangles 105, which is beneficial to further improving the analysis efficiency and the analysis accuracy of the signal eye diagram.

In another embodiment, the obtaining structure may alternatively be configured to use a difference obtained by subtracting a quantity of rectangles included between the second upper boundary and the horizontal axis from a quantity of rectangles included between the first upper boundary and the horizontal axis as the upper offset and use a difference obtained by subtracting a quantity of rectangles included between the first lower boundary and the horizontal axis from a quantity of rectangles included between the second lower boundary and the horizontal axis as the lower offset, that is, both the upper offset and the lower offset represent the quantities of rectangles.

In the two embodiments, the obtaining structure 130 may further be configured to generate a swing margin of the target signal eye diagram based on a sum of the upper offset and the lower offset after obtaining the upper offset and the lower offset. It should be noted that the area of the standard effective region 104 may be changed without changing the center of symmetry of the standard effective region 104, to generate the target effective region, so that the second left boundary is a boundary, located at a leftmost side, of the target effective region, and the second right boundary is a boundary, located at a rightmost side, of the target effective region. The user may determine the quality of the target signal eye diagram based on the target effective region and the target eye diagram effective region. In addition, a manner of determining, based on positive or negative of the upper offset and the lower offset, whether the signal eye diagram is offset is the same as that in the foregoing embodiments. Details are not described herein again.

In addition, in the four embodiments, the area of the standard effective region 104 may be changed without changing the center of symmetry of the standard effective region 104, to generate the target effective region, so that the second left boundary is a boundary, located at the leftmost side, of the target effective region, and the second right boundary is a boundary, located at the rightmost side, of the target effective region. The user may determine the quality of the target signal eye diagram based on the target effective region and the target eye diagram effective region.

Based on the foregoing, different signal eye diagrams are displayed in different ways, and the display of different signal eye diagrams in the display structure 100 does not interference with each other, so that the user can intuitively observe a plurality of signal eye diagrams. In addition, the display structure 100 further displays an outer edge of the standard effective region 104. By respectively comparing position relationships between the signal eye diagrams and the outer edge of the standard effective region 104, the user may intuitively determine whether the quality of the plurality of signal eye diagrams meets a requirement, thereby improving the analysis efficiency of the signal eye diagram.

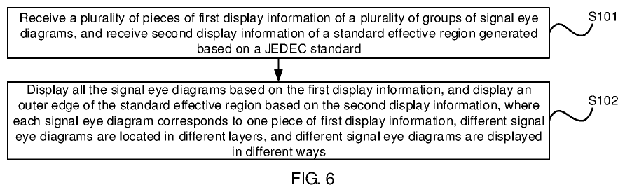

Another embodiment of the present disclosure further provides a method for analysing signal eye diagrams. The method for analysing signal eye diagrams provided by another embodiment of the present disclosure is applicable to the analysis system for signal eye diagrams provided in the foregoing embodiments. FIG. 6 is a flowchart of a method for analysing signal eye diagrams according to another embodiment of the present disclosure. The method for analysing signal eye diagrams provided in another embodiment of the present disclosure is described in detail below with reference to the accompanying drawings.

Referring to FIG. 6, the method for analysing signal eye diagrams includes: S101. Receive a plurality of pieces of first display information of a plurality of groups of signal eye diagrams, and receive second display information of a standard effective region generated based on an industry standard. S102. Display all the signal eye diagrams based on the first display information, and display an outer edge of the standard effective region based on the second display information, where each signal eye diagram corresponds to one piece of first display information, different signal eye diagrams are located in different layers, and different signal eye diagrams are displayed in different ways.

In some embodiments, the displaying different signal eye diagrams in different ways may include: displaying different signal eye diagrams in different colors, where colors displayed in overlapping regions of the plurality of signal eye diagrams are different from a color displayed in a non-overlapping region of any one of the signal eye diagrams. For example, two different signal eye diagrams may be respectively displayed as purple and pink, and an overlapping region between the two signal eye diagrams may be displayed as blue. In an actual application, display modes of different signal eye diagrams and overlapping regions thereof are not limited provided that the user can intuitively distinguish different signal eye diagrams and the overlapping regions.

In some embodiments, the signal eye diagrams may be displayed by using a plurality of rectangles having a same size and closely connected in a grid-like structure. Therefore, it is beneficial to subsequently depending on a quantity of rectangles or representing parameters such as a left offset, a right offset, an upper offset, a lower offset, a timing margin, and a swing margin of the quality of the signal eye diagrams.

In some embodiments, the standard effective region is a central symmetry structure.

The method for analysing signal eye diagrams may further include: changing an area of the standard effective region without changing a center of symmetry of the standard effective region, to generate third display information of a target effective region, and displaying the target effective region based on the third display information.

It should be noted that how to change the area of the standard effective region without changing the center of symmetry of the standard effective region to generate the target effective region is the same as that in the foregoing embodiments. Details are not described herein again.

In some embodiments, the method for analysing signal eye diagrams may further include: setting a first mode and a second mode, where the first mode is used for simulating signal transmission performance of an interface for receiving a data signal, and the second mode is used for simulating signal transmission performance of an interface for receiving a command signal and/or an address signal. The standard effective region generated in the first mode is different from the standard effective region generated in the second mode. Therefore, signal eye diagram analysis may be performed on interfaces with different purposes by using different modes, to simulate and analyze performance of signal channels provided by different interfaces, which is beneficial to improving the analysis accuracy of the signal eye diagram and improving the universality of the analysis system for signal eye diagrams.

In some embodiments, the method for analysing signal eye diagrams may further include: generating fourth display information of eye diagram effective regions in one to one correspondence with the signal eye diagrams based on the signal eye diagrams, and displaying outer edges of the eye diagram effective regions based on the fourth display information, where a type of an area defined by the eye diagram effective region is the same as a type of an area defined by the standard effective region. Therefore, the standard effective region and the eye diagram effective region are generated based on a same standard, to facilitate subsequently determining the quality of the signal eye diagrams based on the standard effective region and the eye diagram effective region.

The method for analysing signal eye diagrams may further include: selecting any eye diagram effective region as a target eye diagram effective region and a signal eye diagram corresponding to the target eye diagram effective region as a target signal eye diagram; and obtaining at least one of a left offset, a right offset, an upper offset, and a lower offset of the target signal eye diagram based on the target eye diagram effective region and the standard effective region.

It should be noted that how to obtain the at least one of the left offset, the right offset, the upper offset, and the lower offset of the target signal eye diagram based on the target eye diagram effective region and the standard effective region is the same as that in the foregoing embodiments. Details are not described herein again. In addition, the standard effective region may be replaced with the target effective region. The area of the standard effective region may be changed without changing the center of symmetry of the standard effective region, to generate the target effective region, and then a timing margin and a swing margin of the target signal eye diagram may be obtained based on the target eye diagram effective region and the target effective region.

Based on the foregoing, different signal eye diagrams are located in different layers, different signal eye diagram are displayed in different ways, and the display of different signal eye diagrams does not interference with each other, so that the user can intuitively observe a plurality of signal eye diagrams. In addition, an outer edge of the standard effective region is further displayed. By respectively comparing position relationships between the signal eye diagrams and the outer edge of the standard effective region 104, the user may intuitively determine whether the quality of the plurality of signal eye diagrams meets a requirement, thereby improving the analysis efficiency of the signal eye diagram.

Those skilled in the art can understand that the above implementations are specific embodiments for implementing the present disclosure. In practical applications, various changes may be made to the above embodiments in terms of form and details without departing from the spirit and scope of the embodiments of the present disclosure. Any person skilled in the art may make changes and modifications to the embodiments without departing from the spirit and scope of the present disclosure. Therefore, the protection scope of the present disclosure should be subject to the scope defined by the claims.

1. An analysis system for signal eye diagrams, comprising:
a display structure, configured to: receive a plurality of pieces of first display information of a plurality of groups of signal eye diagrams, receive second display information of a standard effective region generated based on an industry standard, display all the signal eye diagrams based on the first display information, and display an outer edge of the standard effective region based on the second display information, wherein each signal eye diagram corresponds to one piece of first display information, different signal eye diagrams are located in different layers, and different signal eye diagrams are displayed in different ways.

2. The analysis system for signal eye diagrams according to claim 1, wherein in the display structure, different signal eye diagrams are displayed in different colors, and colors displayed in overlapping regions of the plurality of signal eye diagrams are different from a color displayed in a non-overlapping region of any one of the signal eye diagrams.

3. The analysis system for signal eye diagrams according to claim 1, wherein the signal eye diagram is formed by a plurality of rectangles having a same size and closely connected in a grid-like structure; and the display structure comprises:
a setting unit, configured to set a scale represented by each of a length and a width of the rectangle and set a size of the rectangle and a color displayed in the rectangle.

4. The analysis system for signal eye diagrams according to claim 1, wherein the standard effective region is a central symmetry structure; and the display structure comprises:
a setting unit, configured to change an area of the standard effective region without changing a center of symmetry of the standard effective region, to generate third display information of a target effective region, wherein the display structure displays the target effective region based on the third display information.

5. The analysis system for signal eye diagrams according to claim 4, wherein the setting unit is configured to set a ratio of an area of the target effective region to the area of the standard effective region, to generate the third display information of the target effective region.

6. The analysis system for signal eye diagrams according to claim 4, wherein the setting unit is configured to change at least a side length or a side width of the standard effective region, to generate the third display information of the target effective region.

7. The analysis system for signal eye diagrams according to claim 1, wherein the plurality of signal eye diagrams have overlapping regions, the standard effective region is a central symmetry structure, and the standard effective region has a center of symmetry; and the display structure is configured to:
determine a horizontal coordinate of the center of symmetry based on a midpoint between two points of which horizontal coordinates have a largest difference in the overlapping regions; and
determine a longitudinal coordinate of the center of symmetry based on a midpoint between two points of which longitudinal coordinates have a largest difference in the overlapping regions.

8. The analysis system for signal eye diagrams according to claim 1, wherein the plurality of signal eye diagrams have overlapping regions, the standard effective region is a central symmetry structure, and the standard effective region has a center of symmetry; and the display structure is configured to:
set a horizontal axis and a longitudinal axis that are perpendicular to each other, wherein the horizontal axis represents a scanning period of the signal eye diagram, and the longitudinal axis represents a signal swing of the signal eye diagram;
determine a horizontal coordinate of the center of symmetry based on a midpoint of the scanning period on the horizontal axis; and
determine a longitudinal coordinate of the center of symmetry based on a midpoint on the longitudinal axis.

9. The analysis system for signal eye diagrams according to claim 1, further comprising a generation structure, wherein the generation structure comprises a first mode and a second mode, the first mode is used for simulating signal transmission performance of an interface for receiving a data signal, the second mode is used for simulating signal transmission performance of an interface for receiving a command signal and/or an address signal, and the standard effective region generated by the generation structure in the first mode is different from the standard effective region generated in the second mode.

10. The analysis system for signal eye diagrams according to claim 9, wherein the generation structure is further configured to generate fourth display information of eye diagram effective regions in one to one correspondence with the signal eye diagrams based on the signal eye diagrams; and the display structure is configured to display outer edges of the eye diagram effective regions based on the fourth display information, wherein a type of an area defined by the eye diagram effective region is the same as a type of an area defined by the standard effective region.

11. The analysis system for signal eye diagrams according to claim 10, wherein the display structure is configured to set a horizontal axis and a longitudinal axis that are perpendicular to each other, wherein the horizontal axis represents a scanning period of the signal eye diagram, and the longitudinal axis represents a signal swing of the signal eye diagram; and the analysis system for signal eye diagrams further comprises:
an obtaining structure, configured to:
select any eye diagram effective region as a target eye diagram effective region and the signal eye diagram corresponding to the target eye diagram effective region as a target signal eye diagram, wherein in a direction of the horizontal axis, the target eye diagram effective region has a first left reference value located at a leftmost side and a first right reference value located at a rightmost side, the standard effective region has a second left reference value located at a leftmost side and a second right reference value located at a rightmost side, the first left reference value is subtracted from the second left reference value to generate a left offset, and the second right reference value is subtracted from the first right reference value to generate a right offset.

12. The analysis system for signal eye diagrams according to claim 10, wherein the display structure is configured to set a horizontal axis and a longitudinal axis that are perpendicular to each other, wherein the horizontal axis represents a scanning period of the signal eye diagram, and the longitudinal axis represents a signal swing of the signal eye diagram; and the analysis system for signal eye diagrams further comprises:
an obtaining structure, configured to:
select any eye diagram effective region as a target eye diagram effective region and the signal eye diagram corresponding to the target eye diagram effective region as a target signal eye diagram, wherein in a direction of the longitudinal axis, the target eye diagram effective region has a first upper reference value located at an uppermost end and a first lower reference value located at a lowermost end, the standard effective region has a second upper reference value located at an uppermost end and a second lower reference value located at a lowermost end, the second upper reference value is subtracted from the first upper reference value to generate an upper offset, and the first lower reference value is subtracted from the second lower reference value to generate a lower offset.

13. The analysis system for signal eye diagrams according to claim 10, wherein the signal eye diagram is displayed as a grid-like structure formed by a plurality of rectangles having a same size and closely connected, and the display structure is configured to set a horizontal axis and a longitudinal axis that are perpendicular to each other, wherein the horizontal axis represents a scanning period of the signal eye diagram, and the longitudinal axis represents a signal swing of the signal eye diagram; and the analysis system for signal eye diagrams further comprises:
an obtaining structure, configured to:
select any eye diagram effective region as a target eye diagram effective region and the signal eye diagram corresponding to the target eye diagram effective region as a target signal eye diagram, wherein in a direction of the horizontal axis, the target eye diagram effective region has a first left boundary located at a leftmost side and a first right boundary located at a rightmost side, the standard effective region has a second left boundary located at a leftmost side and a second right boundary located at a rightmost side, a quantity of rectangles comprised between the first left boundary and the longitudinal axis is subtracted from a quantity of rectangles comprised between the second left boundary and the longitudinal axis to generate a left offset value, and a quantity of rectangles comprised between the second right boundary and the longitudinal axis is subtracted from a quantity of rectangles comprised between the first right boundary and the longitudinal axis to generate a right offset value; and
generate a left offset based on a product of the left offset value and a scale represented by a length of the rectangles in the direction of the horizontal axis, and generate a right offset based on a product of the right offset value and a scale represented by the length of the rectangles in the direction of the horizontal axis.

14. The analysis system for signal eye diagrams according to claim 10, wherein the signal eye diagram is displayed as a grid-like structure formed by a plurality of rectangles having a same size and closely connected, and the display structure is configured to set a horizontal axis and a longitudinal axis that are perpendicular to each other, wherein the horizontal axis represents a scanning period of the signal eye diagram, and the longitudinal axis represents a signal swing of the signal eye diagram; and the analysis system for signal eye diagrams further comprises:
an obtaining structure, configured to:
select any eye diagram effective region as a target eye diagram effective region and the signal eye diagram corresponding to the target eye diagram effective region as a target signal eye diagram, wherein in a direction of the longitudinal axis, the target eye diagram effective region has a first upper boundary located at an uppermost end and a first lower boundary located at a lowermost end, the standard effective region has a second upper boundary located at an uppermost end and a second lower boundary located at a lowermost end, a quantity of rectangles comprised between the second upper boundary and the horizontal axis is subtracted from a quantity of rectangles comprised between the first upper boundary and the horizontal axis to generate an upper offset value, and a quantity of rectangles comprised between the first lower boundary and the horizontal axis is subtracted from a quantity of rectangles comprised between the second lower boundary and the horizontal axis to generate a lower offset value; and
generate an upper offset based on a product of the upper offset value and a scale represented by a length of the rectangles in the direction of the longitudinal axis, and generate a lower offset based on a product of the lower offset value and a scale represented by the length of the rectangles in the direction of the longitudinal axis.

15. A method for analysing signal eye diagrams, comprising:
receiving a plurality of pieces of first display information of a plurality of groups of signal eye diagrams, and receiving second display information of a standard effective region generated based on an industry standard; and
displaying all the signal eye diagrams based on the first display information, and displaying an outer edge of the standard effective region based on the second display information, wherein each signal eye diagram corresponds to one piece of first display information, different signal eye diagrams are located in different layers, and different signal eye diagrams are displayed in different ways.

16. The method for analysing signal eye diagrams according to claim 15, wherein the different signal eye diagrams are displayed in different ways comprises: displaying different signal eye diagrams in different colors, wherein colors displayed in overlapping regions of the plurality of signal eye diagrams are different from a color displayed in a non-overlapping region of any one of the signal eye diagrams.

17. The method for analysing signal eye diagrams according to claim 15, wherein the standard effective region is a central symmetry structure, and the method for analysing signal eye diagrams further comprises: changing an area of the standard effective region without changing a center of symmetry of the standard effective region, to generate third display information of a target effective region, and displaying the target effective region based on the third display information.

18. The method for analysing signal eye diagrams according to claim 15, further comprising: setting a first mode and a second mode, wherein the first mode is used for simulating signal transmission performance of an interface for receiving a data signal, the second mode is used for simulating signal transmission performance of an interface for receiving a command signal and/or an address signal, and the standard effective region generated in the first mode is different from the standard effective region generated in the second mode.

19. The method for analysing signal eye diagrams according to claim 15, further comprising: generating fourth display information of eye diagram effective regions in one to one correspondence with the signal eye diagrams based on the signal eye diagrams, and displaying outer edges of the eye diagram effective regions based on the fourth display information, wherein a type of an area defined by the eye diagram effective region is the same as a type of an area defined by the standard effective region.

20. The method for analysing signal eye diagrams according to claim 19, further comprising: selecting any eye diagram effective region as a target eye diagram effective region and the signal eye diagram corresponding to the target eye diagram effective region as a target signal eye diagram; and obtaining at least one of a left offset, a right offset, an upper offset, and a lower offset of the target signal eye diagram based on the target eye diagram effective region and the standard effective region.
